(19) United States
(12) Patent Application Publication
(10) Pub. No.: US 2013/0051418 A1
(43) Pub. Date: Feb. 28, 2013

(54) GROUP III NITRIDE SEMICONDUCTOR LASER DEVICE

(71) Applicants: Takamichi SUMITOMO, Itami-shi (JP); Masaki UENO, Itami-shi (JP); Yusuke YOSHIZUMI, Itami-shi (JP); Takahisa YOSHIDA, Itami-shi (JP); Masahiro ADACHI, Osaka-shi (JP)

(72) Inventors: Takamichi SUMITOMO, Itami-shi (JP); Masaki UENO, Itami-shi (JP); Yusuke YOSHIZUMI, Itami-shi (JP); Takahisa YOSHIDA, Itami-shi (JP); Masahiro ADACHI, Osaka-shi (JP)

(73) Assignee: SUMITOMO ELECTRIC INDUSTRIES, LTD., Osaka-shi (JP)

(21) Appl. No.: 13/556,944

(22) Filed: Jul. 24, 2012

(30) Foreign Application Priority Data
Jul. 26, 2011 (JP) 2011-163458

(51) Int. Cl. H01S 5/323

(52) U.S. Cl. 372/45.01

(57) ABSTRACT

A group-III nitride semiconductor laser device includes an n-type nitride semiconductor region, an active layer provided over the n-type nitride semiconductor region, a first p-type nitride semiconductor region provided over the active layer, a current confinement layer which is provided over the first p-type nitride semiconductor region and has an opening extending in a optical cavity direction, and a second p-type nitride semiconductor region re-grown on the first nitride semiconductor region and the current confinement layer after the formation of the opening of the current confinement layer. The interface between the first p-type nitride semiconductor region and the second p-type nitride semiconductor region includes a semi-polar plane. At least one of the first or second p-type semiconductor regions includes a highly doped p-type semiconductor layer forming an interface with the first and second p-type semiconductor regions and have a p-type impurity level of 1×10²⁰ cm⁻³ or greater.

### BACKGROUND OF THE INVENTION

1. Field of the Invention

This invention relates to a group-III nitride semiconductor laser device.

2. Related Background Art

Patent Literatures 1 to 3 disclose group-III nitride semiconductor laser devices. The group-III nitride semiconductor laser devices disclosed in these patents each include a substrate composed of a group-III nitride semiconductor, an n-type cladding layer of an n-type group-III nitride semiconductor provided on the substrate, an active layer of a group-III nitride semiconductor provided on the n-type cladding layer, a p-type cladding layer of a p-type group-III nitride semiconductor provided on the active layer. An optical guiding layer is provided between the p-type cladding layer and the active layer, and a current confinement layer having an opening for confining current is sandwiched between the optical guiding layer and the p-type cladding layer. A group-III nitride semiconductor laser device having such a structure is fabricated by forming an opening in the current confinement layer and then growing the p-type cladding layer so as to fill the opening. The current confinement layers disclosed in these Patent Literatures are composed of polycrystalline or amorphous AlN.

Patent Literature 1: Japanese Unexamined Patent Application Publication No. 2006-121107.

Patent Literature 2: Japanese Unexamined Patent Application Publication No. 2007-067432.

Patent Literature 3: Japanese Unexamined Patent Application Publication No. 2008-294053.

### SUMMARY OF THE INVENTION

In the fabrication of the group-III nitride semiconductor laser device having the structure as described above, an opening is formed by, for example, etching the current confinement layer. The inventors' findings indicate that impurities such as oxygen and silicon, i.e., n-type dopant, are piled up on a semiconductor surface exposed in the opening of the current confinement layer, (i.e., the re-growth surface on which the p-type cladding layer is to be grown). When a semiconductor layer is re-grown by CVD which uses organic metal materials, the exposed surface is usually cleaned with H₂ or NH₃ at a temperature of 1000 degrees Celsius or higher. The cleaning preferably can remove the above impurities. But, such a high temperature cleaning of the semiconductor structure including the current confinement layer causes modification of the current confinement layer (for example, crystallization), which results in unsatisfactory crystal quality of the layer to be grown (p-type cladding layer) therein. Such a high temperature cleaning cannot be, therefore, applied as a process prior to the re-growth of the p-type cladding layer. Accordingly, the p-type cladding layer is grown on the exposed surface having n-type residual impurities, so that the n-type impurities therein generate non-radiative recombination at the interface between the p-type cladding layer and the optical guiding layer, resulting in current loss thereat. This current loss increases the threshold current density of the semiconductor laser device. The structure in which another p-type semiconductor layer is provided between the p-type cladding layer and the active layer includes a local pnp-structure, and this local structure may increase the drive voltage of the semiconductor laser device.

Such a phenomenon becomes more sever particularly in the semi-polar surface on which the p-type cladding layer is to be re-grown. For example, the group-III nitride semiconductor laser device emitting blue light often uses a c-plane primary surface of group-III nitride semiconductor substrate. In this case, the interface between the p-type cladding layer and the optical guiding layer exhibits a c-plane. In order to reduce the intensity of the piezoelectric field in the active layer, the group-III nitride semiconductor laser device that emits green light uses a substrate of a semi-polar primary surface composed of a group-III nitride semiconductor. In this case, the interface between the p-type cladding layer and the optical guiding layer also exhibits semi-polarity. The findings of the inventors indicate that the semi-polar surface includes a large number of dangling bonds (unpaired bonds) to readily incorporate n-type impurities, as compared with low index planes such as a c-plane, a-plane, and m-plane. As a result, the increase in the above threshold current density and driving voltage becomes remarkable in the semi-polar surface.

It is an object of one aspect of the present invention, which has been accomplished in view of such background, to provide a group-III nitride semiconductor laser device, having a structure in which a p-type cladding layer is re-grown on a current confinement layer having an opening, to reduce the effect caused by the n-type impurities remaining in the semi-polar interface.

To address the above object, a group-III nitride semiconductor laser device according to one aspect of the present invention includes: (a) an n-type semiconductor region comprising an n-type group-III nitride semiconductor; an active layer comprising a group-III nitride semiconductor, the active layer being provided on the n-type semiconductor region; (b) a first p-type semiconductor region comprising a p-type group-III nitride semiconductor, the first p-type semiconductor region being provided on the active layer; (c) a current confinement layer provided on the first p-type semiconductor region and having an opening, the opening extending in a predetermined optical cavity direction; and (d) a second p-type semiconductor region comprising a p-type group-III nitride semiconductor, the second p-type semiconductor region being re-grown on the first p-type semiconductor region and the current confinement layer after the formation of the opening of the current confinement layer. The interface between the first p-type semiconductor region and the second p-type semiconductor region includes the semi-polar surface of the group-III nitride semiconductor; and at least one of the first or second p-type semiconductor regions includes a highly doped p-type semiconductor layer, having a p-type impurity level of 1×10²⁰ cm⁻³ or greater, which forms an interface with the first or second p-type semiconductor region.

In the group-III nitride semiconductor laser device, the interface between the first p-type semiconductor region and the second p-type semiconductor region includes the semi-polar plane of the group-III nitride semiconductor. Since such a structure is achieved in the device including an active layer grown on a semi-polar surface of a group-III nitride semiconductor, the structure can appropriately provide a semiconductor laser device for green emission in which an active layer has a high indium composition. Additionally, in the group-III nitride semiconductor laser device, at least one of the first or second p-type semiconductor regions includes a highly doped p-type semiconductor layer, which forms an interface with the first p-type semiconductor region or the second p-type semiconductor region. In other words, the highly doped p-type semiconductor layer of the first p-type semiconductor region is in contact with the second p-type semiconductor region, or the highly doped p-type semiconductor layer of the second p-type semiconductor region is in contact with the first p-type semiconductor region. The highly doped p-type semiconductor layers contain a p-type impurity in a level of 1×10²⁰ cm⁻³ or greater.

As described above, during the growth of the second p-type semiconductor region on the first p-type semiconductor region, impurities such as oxygen and silicon, which act as donors, are piled up on the surface of the first p-type semiconductor region. In the group-III nitride semiconductor laser device, the p-type impurity (dopant) of the highly doped p-type semiconductor layer, however, diffuses to compensate for the n-type impurity, thereby reducing effects caused by the n-type impurity (increases in threshold current density and drive voltage). Such a group-III nitride semiconductor laser device can reduce effects caused by the n-type impurity present around a semi- polar interface.

In the group-III nitride semiconductor laser device, the highly doped p-type semiconductor layer may have a thickness of 10 nm or less. The findings by the inventors indicate that a half width of the profile of the n-type impurity around the interface is approximately 10 nm in the thickness direction, and that the thickness of the highly doped p-type semiconductor layer is less than 10 nm, a group-III nitride semiconductor laser device has excellent device performances.

In the group-III nitride semiconductor laser device, the highly doped p-type semiconductor layer may be provided only in the first p-type semiconductor region. The group-III nitride semiconductor laser device having such a structure can appropriately provide the advantages described above.

In the group-III nitride semiconductor laser device, the near-side surface of the active layer near the first p-type semiconductor region may be separated at a distance of 200 nm or greater from the near-side surface of the highly doped p-type semiconductor layer near the active layer. Such a large distance between the active layer and the highly doped p-type semiconductor layer can reduce the optical absorption of p-type impurity in the highly doped p-type semiconductor layer and can prevent the deterioration of lasing efficiency. Since the optical absorption by p-type (dopant) impurity greatly occurs in the wavelength region of 500 nm or greater, a lasing wavelength of a laser emission is preferably 500 nm or greater.

The above-described object and other objects, features, and advantages of the present invention will be readily apparent from the following detailed descriptions of the preferable embodiment of the present invention with reference to the accompanying drawings.

### BRIEF DESCRIPTION OF THE DRAWINGS

FIG. 1 is a cross sectional view illustrating a structure of a semiconductor laser device according to an embodiment of the present invention;

FIG. 2 is a cross sectional view illustrating steps of an exemplary method for fabricating the semiconductor laser device in its Parts (a) to (c);

FIG. 3 is a cross sectional view illustrating steps of an exemplary method for fabricating the semiconductor laser device in its Parts (a) to (c);

FIG. 4 is a cross sectional view illustrating steps of an exemplary method for fabricating the semiconductor laser device in its Parts (a) to (c);

FIG. 5 is a sectional view illustrating a step of an exemplary method for fabricating the semiconductor laser device;

FIG. 6 is a sectional view of a structure of the group-III nitride semiconductor laser device as an example;

FIG. 7 is a view showing a secondary ion mass spectroscopy profile in the thickness direction of a semiconductor laser device as an example; and

FIG. 8 is a view illustrating band structures of the semiconductor laser device in its Parts (a) to (c).

### DESCRIPTION OF THE EMBODIMENTS

The teachings of the present invention can be readily apparent from the following detailed descriptions with reference to the accompanying drawings that illustrate typical embodiments. A group-III nitride semiconductor laser device according to an embodiment of the present invention will now be described with reference to the accompanying drawings. If possible, the same reference numerals are assigned to the same components.

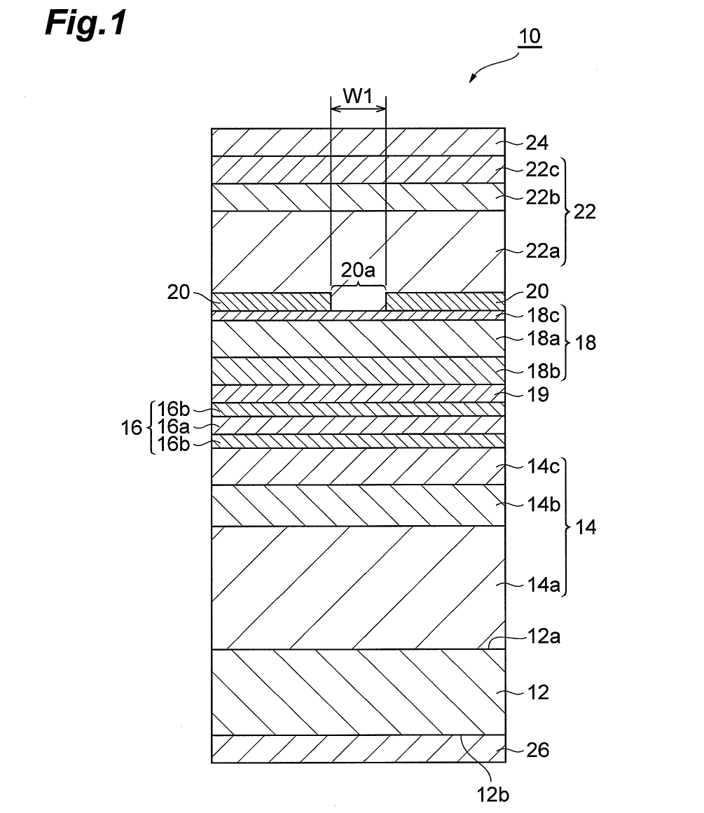

FIG. 1 is a view illustrating the structure of a semiconductor laser device 10 according to an embodiment of the present invention, and the cross-section or end face thereof is taken along the line vertical to the optical cavity direction. The semiconductor laser device 10 can include a group-III nitride semiconductor laser device which can emit green laser light having an emission wavelength in the range of 500 nm to 540 nm. The semiconductor laser device 10 includes a semiconductor substrate 12 as a support, an n-type semiconductor region 14, an active layer 16, a first p-type semiconductor region 18, a current confinement layer 20, a second p-type semiconductor region 22, an anode 24, and a cathode 26. The semiconductor laser device 10 can be of an edge-emitting type. The laser cavity of the semiconductor laser device 10 extends in the direction in which a plane parallel to the primary surface of the support extends. A pair of end faces for the laser cavity intersects the plane parallel to the primary surface of the support. In the semiconductor laser device 10, the end faces of the laser cavity may have the same structure as that of the cross-section vertical to the optical cavity direction, as is illustrated in FIG. 1.

The semiconductor substrate 12 is composed of a group-III nitride semiconductor, and in an example, is composed of n-type GaN. The semiconductor substrate 12 has a primary surface 12a including a semi-polar plane of a group-III nitride semiconductor crystal, and a back surface 12b. The c-axis of the group-III nitride of the semiconductor substrate 12 tilts from the normal axis of the primary surface 12a. The tilt angle of the primary surface 12a of the semiconductor substrate 12 is defined as an angle formed by the normal vector of the primary surface 12a and the c-axis. The tilt angle may be in the range of 10 degrees to 80 degrees or 100 degrees to 170 degrees. When the semiconductor substrate 12 is composed of, for example, GaN, the primary surface 12a tilting in an angle in the above angle exhibits semi-polarity of GaN. The c-axis of the group-III nitride constituting the semiconductor substrate 12 preferably tilts toward the m-axis of group-III nitride semiconductor of the semiconductor substrate 12. The tilt angle may be in the range of 63 degrees to 80 degrees or 100 degrees to 117 degrees. Such a range of angle allows the formation of an InGaN layer having a desirable indium composition suitable for an active layer 16 (described below) emitting light of 500 nm or greater. More preferably, the c-axis of the group-III nitride of the semiconductor substrate 12 is inclined toward the m-axis at an inclination angle of approximately 75 degrees with respect to the primary surface 12a. The primary surface 12a can be typically a {20-21} surface.

The n-type semiconductor region 14 is composed of an n-type group-III nitride semiconductor. The n-type semiconductor region 14 is provided on the primary surface 12a of the semiconductor substrate 12, and includes one or more semiconductor layers grown along the normal line of the primary surface 12a. The n-type semiconductor region 14 of an example includes an n-type cladding layer 14a, a first lower optical guiding layer 14b, and a second lower optical guiding layer 14c, which are grown on the primary surface 12a in sequence.

The n-type cladding layer 14a may be composed of an n-type group-III nitride semiconductor, such as a nitride gallium-based semiconductor. The first lower optical guiding layer 14b may be composed of a group-III nitride semiconductor, such as a nitride gallium-based semiconductor. The second lower optical guiding layer 14c may be composed of a group-III nitride semiconductor such as a nitride gallium-based semiconductor. In one embodiment, the n-type cladding layer 14a may be composed of, for example, n-type AlGaN or n-type InAlGaN; the first lower optical guiding layer 14b may be composed of, for example, n-type GaN; and the second lower optical guiding layer 14c may be composed of, for example, n-type InGaN. The indium composition of the second lower optical guiding layer 14c is, for example, 0.025. The n-type cladding layer 14a, the first lower optical guiding layer 14b, and the second lower optical guiding layer 14c have a thickness of, for example, 1200 nm, 250 nm, and 150 nm, respectively. Additionally, the n-type cladding layer 14a, the first lower optical guiding layer 14b, and the second lower optical guiding layer 14c contains an n-type impurity (dopant) such as Si, and the concentration of the dopants is, for example, 2×10¹⁸ cm⁻³.

The active layer 16 may include one or more layers having a quantum well structure (single- or multi-quantum well structure). FIG. 1 illustrates a single-quantum well structure including a well layer 16a disposed between barrier layers 16b. The well layer 16a may be composed of, for example, InGaN, and the barrier layer 16b may be composed of, for example, GaN or InGaN. In one embodiment, the thickness of the well layer 16a is, for example, 2.5 nm, and the thickness of the barrier layers 16b is, for example, 10 nm. The emission wavelength of the active layer 16 depends on the bandgap, the indium composition, and thickness of the well layer 16a. In one embodiment, the indium composition of the well layer 16a can be, for example, 0.20, and such an indium composition allows the well layer 16a to emit green light having a wavelength of, for example, 510 nm.

The first p-type semiconductor region 18 is composed of a p-type group-III nitride semiconductor. The first p-type semiconductor region 18 is provided on the active layer 16, and includes one or more semiconductor layers grown along the normal line of the primary surface 12a. The first p-type semiconductor region 18 in an example includes a second upper optical guiding layer 18b and a first upper optical guiding layer 18a which are arranged on the active layer 16 in sequence. If needed, an undoped third upper optical guiding layer 19 may be provided between the second upper optical guiding layer 18b and the active layer 16.

As described above, the primary surface 12a of the semiconductor substrate 12 includes the semi-polar surface of the group-III nitride semiconductor. The n-type semiconductor region 14, the active layer 16, and the first p-type semiconductor region 18 are grown along the normal axis of the semi-polar surface in sequence. The surface of the n-type semiconductor region 14 thus exhibits semi-polarity of a group-III nitride semiconductor, so that the surface of the active layer 16 exhibits semi-polarity of a group-III nitride semiconductor. This allows the surface of the first p-type semiconductor region 18 (which forms an interface with a second p-type semiconductor region 22, as described below) to include the semi-polar surface of the group-III nitride semiconductor.

The second upper optical guiding layer 18b may be composed of a group-III nitride semiconductor, such as a nitride gallium-based semiconductor. The first upper optical guiding layer 18a may be composed of a group-III nitride semiconductor, such as a nitride gallium-based semiconductor. In an example, the first upper optical guiding layer 18a may be composed of, for example, p-type GaN, and the second upper optical guiding layer 18b may be composed of, for example, p-type InGaN. The indium composition of the second upper optical guiding layer 18b can be, for example, 0.025. The second upper optical guiding layer 18b and the first upper optical guiding layer 18a have a thickness of 40 nm and 200 nm, respectively. Additionally, the second upper optical guiding layer 18b and the first upper optical guiding layer 18a contain a p-type impurity (dopant) such as Mg. The p-type impurity (dopant) concentration of the first upper optical guiding layer 18a is in the range of, for example, 5×10¹⁷ cm³ to 3×10¹⁸ cm⁻³, and can be preferably, 1×10¹⁸ cm⁻³. The first upper optical guiding layer 18a has a thickness ranging, for example, from 40 nm to 200 nm. The p-type dopant concentration of the second upper optical guiding layer 18b is in the range of, for example, 1×10¹⁷ cm⁻³to 1×10¹⁹ cm⁻³, and can be preferably, 1×10¹⁸ cm⁻³. The second upper optical guiding layer 18b has a thickness ranging, for example, from 100 nm to 300 nm. The indium composition of the second upper optical guiding layer 18b may range, for example, from 0.2 to 0.4. The third upper optical guiding layer 19 may be composed of an undoped group-III nitride semiconductor, such as an undoped nitride gallium-based semiconductor. In an example, the third upper optical guiding layer 19 may be composed of InGaN. The indium composition of the third upper optical guiding layer 19 can be, for example, 0.025. The third upper optical guiding layer 19 has a thickness of, for example, 80 nm.

The current confinement layer 20 is composed of an amorphous or polycrystalline group-III nitride semiconductor (such as AlN) grown on the first p-type semiconductor region 18. The current confinement layer 20 is preferably formed by growing a group-III nitride semiconductor at a low temperature (for example, 500 degrees Celsius). The current confinement layer 20 has an opening 20a extending in the predetermined direction of the optical cavity. The current confinement layer 20 guides current applied to the group-III nitride semiconductor laser device 10 to flow through the opening 20a, thereby providing current confinement. The width W1 of the opening 20a in the direction orthogonal to the predetermined optical cavity direction may range from 1 μm to 10 μm, for example, 2 μm. The length of the opening 20a, which extends from one end face to the other end face of the cavity in the predetermined optical cavity direction, is same as the length of the cavity, and can be, for example, 600 μm. The opening 20a extending in the optical cavity direction may have, for example, a stripe shape, and the length of the opening 20a may range, for example, from 400 μm to 1000 μm. The current confinement layer 20 may have a depth ranging, for example, from 5 nm to 20 nm, and for example, of 10 nm.

The second p-type semiconductor region 22 is composed of a p-type group-III nitride semiconductor. The second p-type semiconductor region 22 is provided on the current confinement layer 20 and the first p-type semiconductor region 18 so as to fill the opening 20a of the current confinement layer 20. After the formation of the opening 20a, the second p-type semiconductor region 22 is re-grown on the first p-type semiconductor region 18 and the current confinement layer 20. The second p-type semiconductor region 22 includes one or more semiconductor layers, which are grown along the normal line of the primary surface 12a. The second p-type semiconductor region 22 in an example includes a p-type cladding layer 22a, a lower contact layer 22b, and an upper contact layer 22c, each of which is grown on the current confinement layer 20 and the first p-type semiconductor region 18 in sequence. The first p-type semiconductor region 18, the current confinement layer 20, and the second p-type semiconductor region 22 constitutes a group-III nitride region, which is provided on the active layer 16.

The p-type cladding layer 22a is composed of a p-type group-III nitride semiconductor. The lower contact layer 22b is composed of a p-type group-III nitride semiconductor. The upper contact layer 22c is composed of a p-type group-III nitride semiconductor. In an example, the p-type cladding layer 22a may be composed of, for example, p-type AlGaN or p-type InAlGaN, the lower contact layer 22b may be composed of p-type GaN, and the upper contact layer 22c may be composed of highly doped p-type GaN of a p-type dopant concentration greater than that of the lower contact layer 22b. The p-type cladding layer 22a has a p-type dopant concentration less than that of the lower contact layer 22b. The p-type cladding layer 22a, the lower contact layer 22b, and the upper contact layer 22c have a thickness of, for example, 400 nm, 40 nm, 10 nm, respectively. Additionally, the p-type cladding layer 22a, the lower contact layer 22b, and the upper contact layer 22c contain a p-type impurity (dopant) such as Mg. The p-type impurity (dopant) concentration of the p-type cladding layer 22a is in a range, for example, of 5×10¹⁸ cm⁻³ to 2×10¹⁹ cm⁻³, and can be preferably, 1×10¹⁹ cm⁻³. Since the current confinement layer 20 is composed of a polycrystalline and/or amorphous group-III nitride semiconductor (for example, AlN) as described above, the p-type cladding layer 22a grown on the current confinement layer 20 can have excellent crystallinity, and can prevent the p-type cladding layer 22a from cracking. The current confinement layer can be composed of AlN having a wide bandgap allowing excellent insulation properties, or AlGaN having a high Al composition, and AlN or AlGaN of single crystal may create noticeable misfit dislocation due to lattice mismatch therebetween.

An anode 24 is provided on the upper contact layer 22c of the second p-type semiconductor region 22, and forms an ohmic contact with the upper contact layer 22c. The anode 24 is formed on the upper contact layer 22c by evaporation and is composed of, for example, Pd, and the anode 24 has a thickness of, for example, 100 nm. A cathode 26 is provided on the back surface 12b of the semiconductor substrate 12, and forms an ohmic contact with the semiconductor substrate 12. The cathode 26 is formed on the back surface 12b and is composed of, for example, Ti/Al.

The first p-type semiconductor region 18 of the embodiment further includes a highly doped p-type semiconductor layer 18c. The highly doped p-type semiconductor layer 18c is provided on the top of the first p-type semiconductor region 18 such that the first p-type semiconductor region 18 and the second p-type semiconductor region 22 form an interface. The highly doped p-type semiconductor layer 18c is provided on a first upper optical guiding layer 18a, and is sandwiched between the first upper optical guiding layer 18a and the p-type cladding layer 22a and current confinement layer 20. At least one of the first or second p-type semiconductor regions 18 and 22 includes the highly doped p-type semiconductor layer 18c, which has a p-type impurity level of 1×10²⁰ cm⁻³ or greater, such that the first p-type semiconductor region 18 and the second p-type semiconductor region 22 form an interface.

The highly doped p-type semiconductor layer 18c is composed of a p-type group-III nitride semiconductor, such as a nitride gallium-based semiconductor. In one example, the highly doped p-type semiconductor layer 18c may be composed of, for example, p-type GaN. The highly doped p-type semiconductor layer 18c has a relatively high concentration of p-type impurity (dopant) ranging, for example, from 1×10²⁰ cm⁻³ to 3×10²⁰ cm⁻³. This concentration of p-type impurity (dopant) is significantly greater than that of the first upper optical guiding layer 18a adjacent to the p-type semiconductor layer 18c and that of the p-type cladding layer 22a, by for example, one to two digits. The p-type impurity (dopant) contained in the highly doped p-type semiconductor layer 18c can be, for example, Mg. The thickness of the highly doped p-type semiconductor layer 18c can be preferably 10 nm or less. The thickness of the highly doped p-type semiconductor layer 18c can be preferably 5 nm or greater. The p-type dopant concentration of the highly doped p-type semiconductor layer 18c is greater than the peak concentration of donor impurity in there-growth surface.

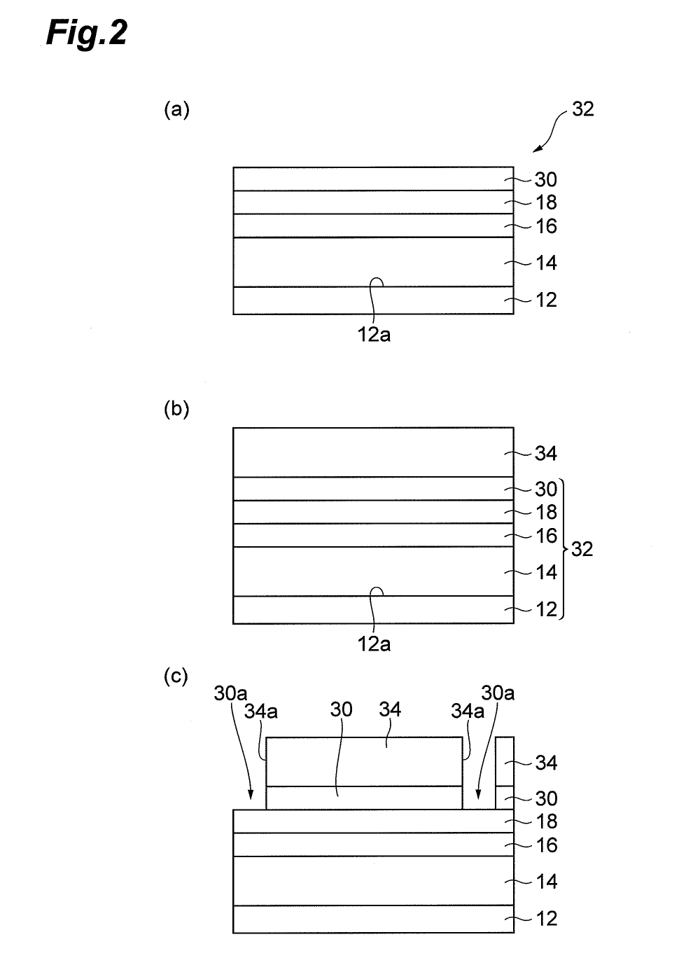

The semiconductor laser device 10 having the structure described above is fabricated through, for example, the following steps. FIGS. 2 to 5 are cross-sectional views, taken along the line vertical to the optical cavity direction, illustrating primary steps for fabricating a semiconductor laser device 10 in an example. NH₃ and organic metal materials such as, TMG, TMA, and TMI are used for the growth of semiconductor described below. Silane gas is used as material for an n-type dopant (such as Si) and Cp₂Mg for p-type dopant (such as Mg).

A semiconductor substrate 12 (for example, an n-type GaN substrate) is prepared which has the primary surface 12a of a {20-21} plane of GaN. The primary surface 12a of the semiconductor substrate 12 is thermally-processed at a high temperature of 1100 degrees Celsius in an NH₃ atmosphere. As illustrated in Part (a) of FIG. 2, an n-type semiconductor region 14, an active layer 16, an optional third upper optical guiding layer 19 (shown in FIG. 1), and a first p-type semiconductor region 18 are epitaxially grown on the primary surface 12a of the semiconductor substrate 12 sequentially. Organometallic vapor phase epitaxy can be applied to the epitaxial growth, and the epitaxial growth can be carried out in the growth reactor. In the epitaxial growth, the n-type cladding layer 14a (for example, an n-type InAlGaN layer) and a first lower optical guiding layer 14b (for example, an n-type GaN layer) of the n-type semiconductor region 14 are grown at the growth temperature of, for example, 900 degrees Celsius, and a second lower optical guiding layer 14c (for example, an n-type InGaN layer) is grown at the growth temperature of, for example, 870 degrees Celsius. The well layer 16a (for example, an undoped InGaN layer) of the active layer 16 is grown at the growth temperature of, for example, 700 degrees Celsius, and the barrier layers 16b (for example, undoped GaN layers) are grown at the growth temperature of, for example, 800 degrees Celsius. The second upper optical guiding layer 18b (for example, a p-type InGaN layer) of the first p-type semiconductor region 18 is grown at the growth temperature of, for example, 800 degrees Celsius; the first upper optical guiding layer 18a (for example, p-type GaN layers) are grown at the growth temperature of, for example, 900 degrees Celsius; and the highly doped p-type semiconductor layer 18c (for example, a highly doped p-type GaN layer) is grown at the growth temperature of, for example, 900 degrees Celsius. An AlN layer 30 for a current confinement layer 20 is grown on the first p-type semiconductor region 18. The temperature of the growth of the current confinement layer 20 is lower than those of the semiconductor layers that have been grown therebefore: the temperature of the growth of the AlN layer 30 is, for example, 500 degrees Celsius. As a result, a substrate product 32 including the n-type semiconductor region 14, the active layer 16, the first p-type semiconductor region 18, and the AlN layer 30 is fabricated.

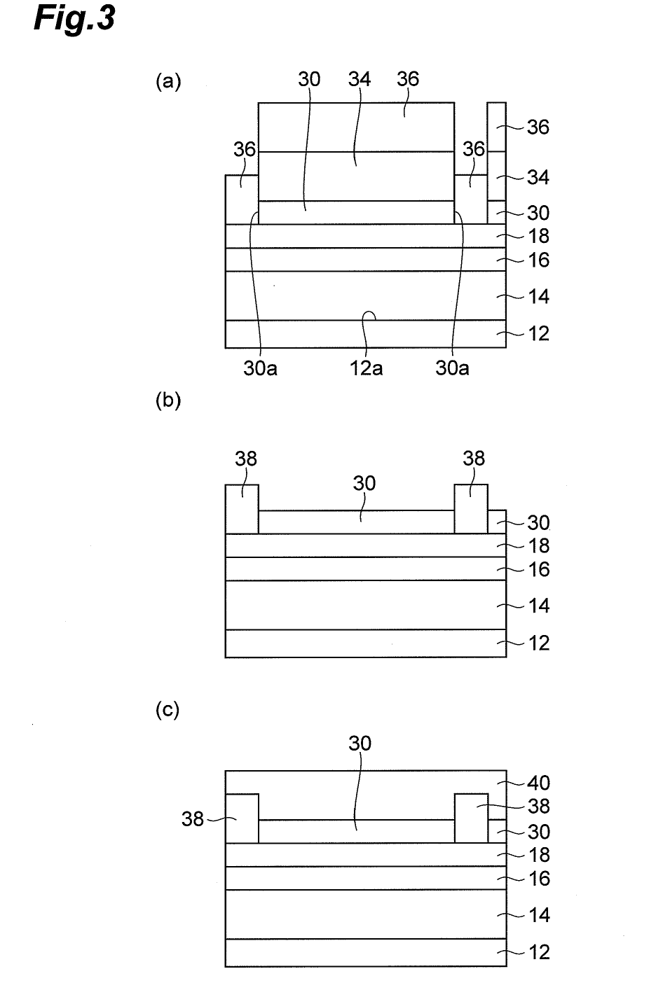

The substrate product 32 is then taken out from the growth reactor and is patterned to form alignment marks as illustrated in Part (b) of FIG. 2. For example, a photoresist layer is applied to the AlN layer 30, in order to form the alignment marks. The photoresist layer is patterned by photolithography to provide a mask 34 having openings 34a as illustrated in Part (c) of FIG. 2. The AlN layer 30 is etched using the photoresist mask 34 thereon to provide openings 30a for alignment marks. As illustrated in Part (a) of FIG. 3, an insulating layer, such as ZrO₂ layers 36, is grown over the patterned photoresist layers 34 and the first p-type semiconductor region 18 within the openings 30a in the growth reactor for vacuum electron-beam evaporation by ion beam evaporation of zirconium oxide (such as ZrO₂), which is used as material for the alignment mark, over the patterned substrate product 32. The ZrO₂ layers 36 is then removed (lifted-off) along with the photoresist layer 34 formed thereon to provide alignment marks 38 composed of ZrO₂ as illustrated in Part (b) of FIG. 3.

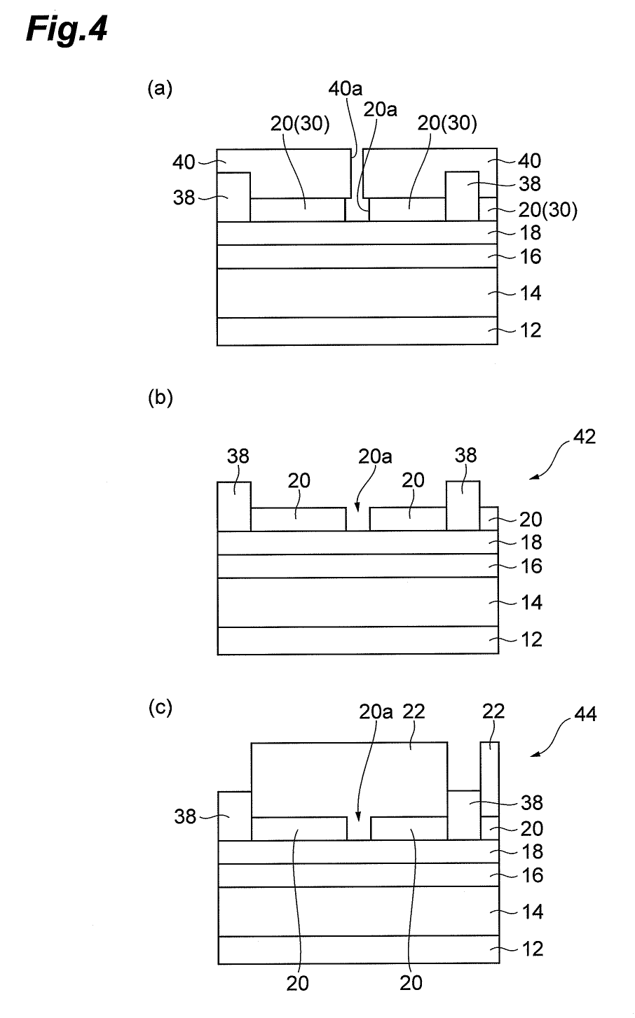

A photoresist layer 40 is applied onto the AlN layers 30 and alignment marks 38, as illustrated in Part (c) of FIG. 3. The photoresist mask 40 having openings 40a is formed by patterning though photolithography, as illustrated in Part (a) of FIG. 4. The openings 40a are not located on the alignment marks 38. The etching of the AlN layer 30 using the photoresist layer 40 grown thereon (preferably wet-etching with KOH solution) is carried out using an etching apparatus, to form an opening in the AlN layer 30, which provides a current confinement layer 20 having an opening 20a for confining current. The photoresist layer 40 is then removed as illustrated in Part (b) of FIG. 4. A substrate product 42 including a current confinement layer 20 is fabricated through these steps. The surface of first p-type semiconductor region 18 is exposed in the openings of the etched AlN layer 30.

The substrate product 42 is placed in the growth reactor again to epitaxially grow a second p-type semiconductor region 22 on the current confinement layer 20 and the first p-type semiconductor region 18 located in the openings 20a, as illustrated in Part (c) of FIG. 4. A p-type cladding layer 22a (for example, a p-type InAlGaN layer) of the second p-type semiconductor region 22 is grown at the growth temperature of, for example, 800 degrees Celsius, while an lower contact layer 22b (for example, a p-type GaN layer) and an upper contact layer 22c (for example, a highly doped p-type GaN layer) are grown at the growth temperature of, for example, 900 degrees Celsius. A substrate product 44 including the second p-type semiconductor region 22 is provided through these steps.

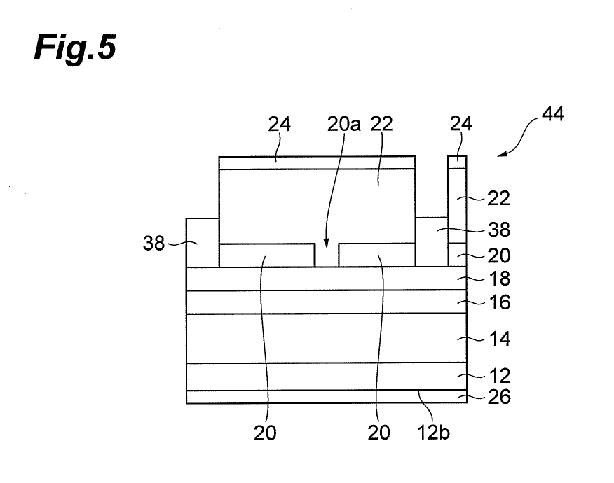

An anode 24 (for example, Pd) is formed by evaporation on the second p-type semiconductor region 22 of the substrate product 44, as illustrated in FIG. 5. A part of the anode 24, which is located on the region that is to be scribed (described below), is then etched using alignment marks 38. A cathode 26 (Ti/Al) is evaporated on the back surface 12b of the semiconductor substrate 12. The substrate product 44 is cleaved to form end faces for a cavity, and the end faces extend along respective planes intersecting the optical cavity direction. Thereafter, the separation (scribing) at breaking planes extending along the optical cavity direction is carried out into chips. Through these steps, semiconductor laser devices 10 are produced which have the structure illustrated in FIG. 1. The semiconductor laser device 10 fabricated actually by the method according to the embodiment exhibits a threshold current of 58 mA, a threshold voltage of 5.9 V, and an emission wavelength of 510 nm.

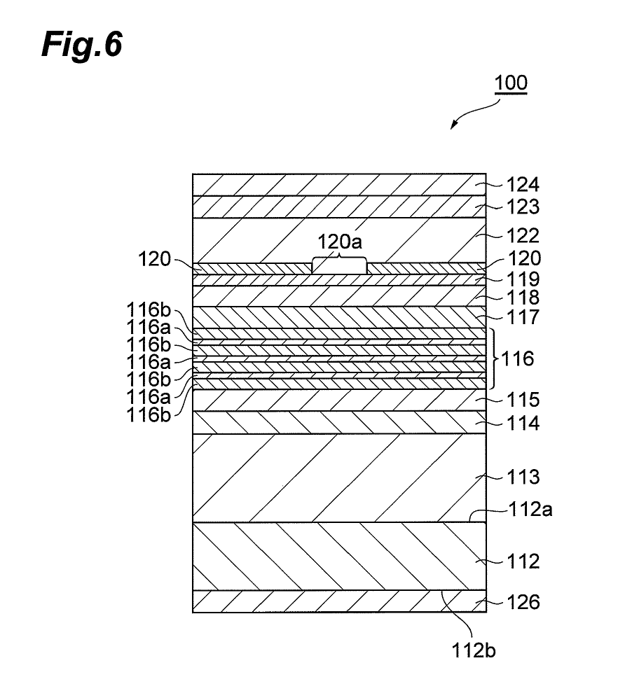

Technical contributions of the semiconductor laser device 10 having such a structure according to an embodiment described above are now described along with the problems of the conventional semiconductor laser device. FIG. 6 is a cross-sectional view, taken along the line vertical to the optical cavity direction, of the group-III nitride semiconductor laser device 100 as an example. The semiconductor laser device 100 includes a semiconductor substrate 112 as a support, an n-type cladding layer 113, a first lower optical guiding layer 114, a second lower optical guiding layer 115, an active layer 116, a third upper optical guiding layer 117, a second upper optical guiding layer 118, a first upper optical guiding layer 119, a current confinement layer 120, a p-type cladding layer 122, a p-type contact layer 123, an anode 124, and a cathode 126.

The semiconductor substrate 112 is composed of, for example, a group-III nitride semiconductor such as n-type GaN. The semiconductor substrate 112 has a primary surface 112a of, for example, a c-plane ({0001} plane) of a group-III nitride semiconductor crystal, and a back surface 112b. In an example, the c-axis of the group-III nitride of the semiconductor substrate 112 is substantially identical to the normal axis of the primary surface 112a. The primary surface 112a as described above allows the formation of an InGaN layer having a desirable indium composition suitable for an active layer 116 (described below) to emit light having the emission wavelength range of less than 500 nm.

An n-type cladding layer 113 and a first lower optical guiding layer 114 are provided on the primary surface 112a of the semiconductor substrate 112 in sequence. The n-type cladding layer 113 is composed of an n-type group-III nitride semiconductor. The first lower optical guiding layer 114 is composed of an n-type group-III nitride semiconductor. The n-type cladding layer 113 is composed of, for example, n-type Al_{0.04}Ga_{0.96}N, while the first lower optical guiding layer 114 is composed of, for example, n-type GaN. The thickness values of the n-type cladding layer 113 and the first lower optical guiding layer 114 are, for example, 2300 nm and 50 nm, respectively. The n-type cladding layer 113 and the first lower optical guiding layer 114 comprises an n-type impurity (dopant) such as Si, and the dopant concentration can be, for example, 2×10¹⁸ cm⁻³.

A second lower optical guiding layer 115 is provided on the first lower optical guiding layer 114. The second lower optical guiding layer 115 is composed of an undoped group-III nitride semiconductor, such as a nitride gallium-based semiconductor. The second lower optical guiding layer 115 is composed of, for example, In_{0.04}Ga_{0.96}N, and has a thickness of, for example, 50 nm.

The active layer 116 has a multiple quantum well structure, which includes plural well layers 116a and barrier layers 116b, which are alternately arranged. The active layer 116 illustrated in FIG. 6 includes three layers as the well layers 116a. Each well layer 116a is composed of, for example, InGaN, while each barrier layer 116b is composed of, for example, GaN or InGaN. The well layer 116a has a thickness of, for example, 3 nm, while the barrier layer 116b has a thickness of, for example, 15 nm.

A third upper optical guiding layer 117 is provided on the active layer 116. The third upper optical guiding layer 117 is composed of an undoped group-III nitride semiconductor. The third upper optical guiding layer 117 is composed of, for example, In_{0.04}Ga_{0.96}N, and has a thickness of, for example, 50 nm. A second upper optical guiding layer 118 is provided on the third upper optical guiding layer 117. The second upper optical guiding layer 118 is composed of a p-type group-III nitride semiconductor. The second upper optical guiding layer 118 is composed of, for example, p-type GaN, and has a thickness of, for example, 50 nm. A first upper optical guiding layer 119 is provided on the second upper optical guiding layer 118. The first upper optical guiding layer 119 is composed of a p-type group-III nitride semiconductor. The first upper optical guiding layer 119 is composed of, for example, p-type Al_{0.18}Ga_{0.82}N, and has a thickness of, for example, 20 nm. The first to third upper optical guiding layers 117 to 119 contain a p-type impurity (dopant) such as Mg. The p-type impurity (dopant) concentration of the first upper optical guiding layer 119 can be, for example, 1×10¹⁸ cm⁻³.

The primary surface 112a of the semiconductor substrate 112 includes a c-plane of a group-III nitride semiconductor as described above. Accordingly, the surface of the first upper optical guiding layer 119 grown along the crystal axis of the group-III nitride semiconductor (the interface between the first upper optical guiding layer 119 and a p-type cladding layer 122 which will be described below) also has the polarity of a group-III nitride semiconductor.

The current confinement layer 120 is composed of a polycrystalline or amorphous group-III nitride semiconductor (such as AlN), which is grown over the first upper optical guiding layer 119. The structure of the current confinement layer 120, such as the shape of the opening 120a, is identical or similar to that of the current confinement layer 20 described above (see FIG. 1).

A p-type cladding layer 122 and a p-type contact layer 123 are composed of a p-type group-III nitride semiconductor. The p-type cladding layer 122 is grown over the current confinement layer 120 and the first upper optical guiding layer 119 such that the layer 122 is embedded in the opening 120a of the current confinement layer 120. After forming the opening 120a of the current confinement layer 120, the p-type cladding layer 122 is re-grown over the current confinement layer 120 and the first upper optical guiding layer 119. The p-type cladding layer 122 is composed of, for example, p-type Al_{0.06}Ga_{0.94}N, whereas a p-type contact layer 123 is composed of, for example, highly doped p-type GaN. The thickness values of the p-type cladding layer 122 and p-type contact layer 123 have, for example, 500 nm and 50 nm, respectively. The p-type cladding layer 122 and the p-type contact layer 123 contain a p-type impurity (dopant) such as Mg, and the impurity (dopant) concentration of the p-type cladding layer 122 is, for example, 1×10¹⁸ cm⁻³.

An anode 124 is provided on the p-type contact layer 123, and forms an ohmic contact to the p-type contact layer 123. A cathode 126 is provided on the back surface 112b of the semiconductor substrate 112, and forms an ohmic contact to the semiconductor substrate 112.

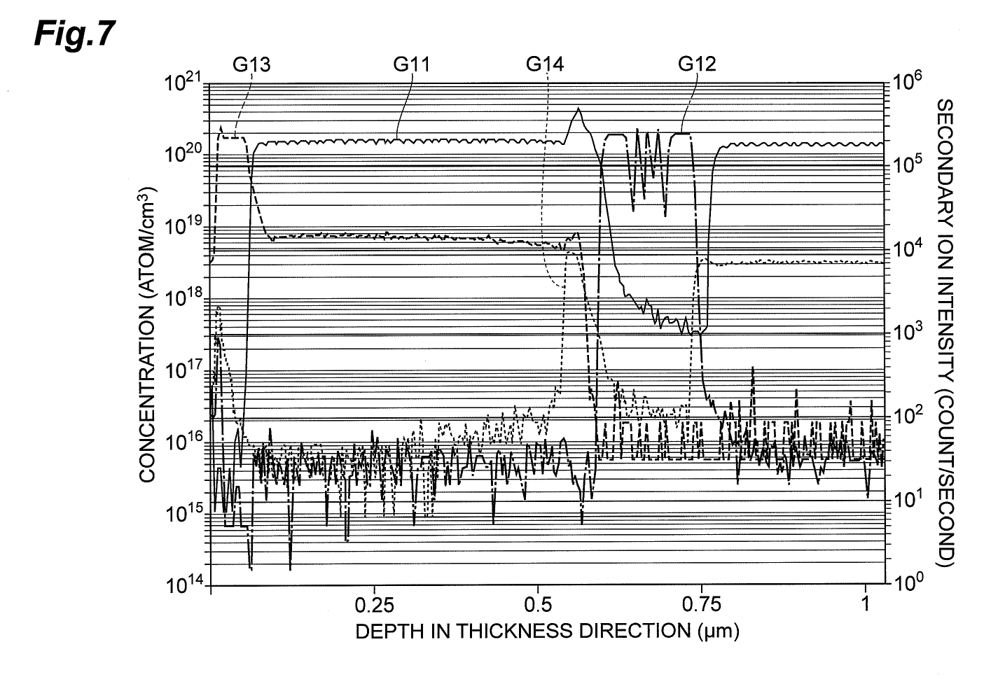

FIG. 7 is a spectrum representing the depth profile of atoms observed in the thickness direction of the semiconductor laser device 100 with secondary ion mass spectroscopy. In FIG. 7, the vertical axis indicates the depth in the thickness direction of the semiconductor laser device 100 (the origin represents the surface of the p-type contact layer 123), and the horizontal axis represents secondary ionic strength (or atomic concentration). In FIG. 7, Graph G11 represents the concentration profile of Al (aluminum), and Graph G12 represents the concentration profile of In (indium). Graph G13 represents the concentration profile of Mg (magnesium) working as a p-type impurity (dopant), and Graph G14 represents the concentration profile of Si working as an n-type impurity which is unintentionally doped during the growth that is performed after the growth of the active layer.

Graph G14 of FIG. 7 reveals that the concentration of silicon, which is an unintentionally doped donor impurity, has a maximum around the depth of around 0.55 μm (corresponding to around the interface between the first upper optical guiding layer 119 and the p-type cladding layer 22a in the p-type semiconductor region) in the semiconductor laser device 100 shown as an example. This interface is apart from the active layer at some distance, whereas the current confinement layer adjacent to the interface can provide excellent confinement of current flowing toward the active layer. The level of the donor impurity is substantially equal to or greater than the level of silicon which is intentionally doped in the growth of the n-type cladding layer 113 and the first lower optical guiding layer 114.

The findings by the inventors suggest that the silicon concentration has such a peak due to the following reasons. During the fabrication of the semiconductor laser device 100 of the above-described structure, the opening 120a of the current confinement layer 120 is formed through etching of the current confinement layer 120. During the etching, donor impurities, such as oxygen and silicon, are piled-up on the exposed surface of the first upper optical guiding layer 119 in the opening 120a of the current confinement layer 120, i.e., the interface between the first upper optical guiding layer 119 and the p-type cladding layer 122. The thermal cleaning of the growth surface exposed may be carried out with, for example, H₂ or NH₃ at a temperature of 1000 degrees Celsius or higher before a growth of a semiconductor layer by CVD which uses organic metal materials. This cleaning allows preferable removal of the above-described impurity that is unintentionally deped. Such a high temperature thermal cleaning of the device including the current confinement layer 120, however, causes a crystallization of the current confinement layer of amorphous material, thereby providing the grown layer (the p-type cladding layer 122) with a poor crystal quality. The current confinement layer 120 is composed of a group-III nitride semiconductor having a wide bandgap, excellent insulation and large lattice constant; however, crystallization of such a semiconductor leads to generation of misfit dislocations in the p-type cladding layer, resulting in a poor crystal quality thereof. Accordingly, such a high temperature cleaning cannot be employed before the growth of the p-type cladding layer 122.

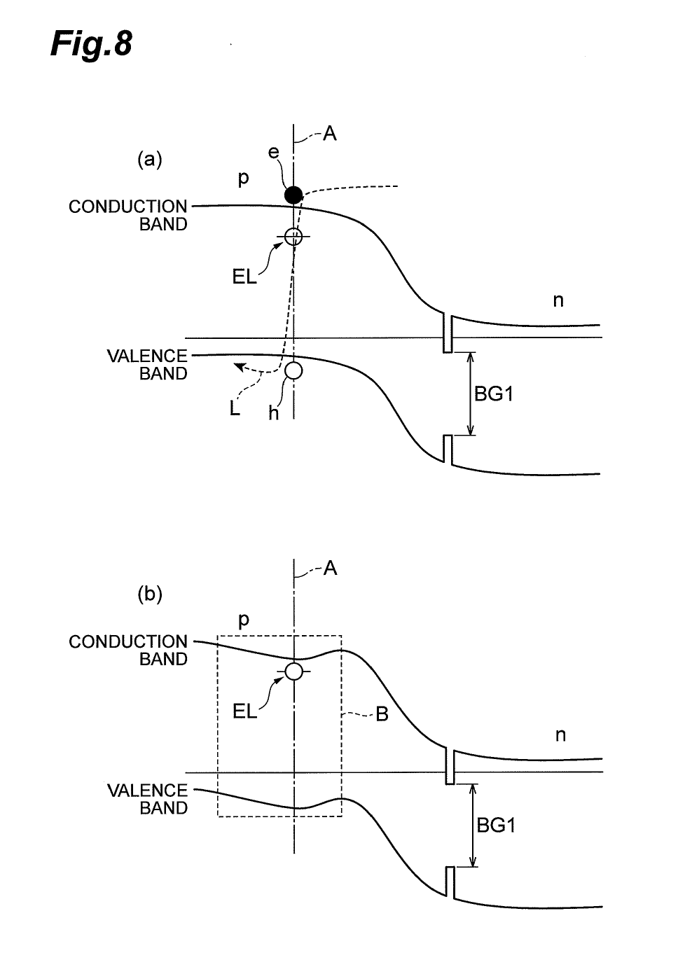

The p-type cladding layer 122 is thus grown on the interface having donor residual impurities thereon. Parts (a) and (b) of FIG. 8 are diagrams illustrating the band structures of the semiconductor laser device 100. In Parts (a) and (b) of FIG. 8, the reference numerals BG1 represents the band gap of the well layer 116a, and the dashed line A indicates the interface between the first upper optical guiding layer 119 and the p-type cladding layer 122. As illustrated in Part (a) of FIG. 8, the residual n-type impurity piled up at the interface between the first upper optical guiding layer 119 and the p-type cladding layer 122 generates an energy level EL around the interface A. The energy level EL causes non-radiative recombination of electrons “e” in the conduction band and holes “h” in the valence band. This recombination leads to the loss of current flowing to the active layer (shown by an arrow L). The recombination increases the threshold current density of the semiconductor laser device 100. Furthermore, the p-type semiconductor region (the first upper optical guiding layer 119) between the interface A and the active layer 116 forms a local pnp-structure, as illustrated in Part (b) of FIG. 8, which increases the driving voltage of the semiconductor laser device 100.

In the semiconductor laser device 10 illustrated in FIG. 1, etching the current confinement layer 20 also forms the opening 20a thereof (see Parts (a) and (b) of FIG. 4). Accordingly, donor impurities such as oxygen and silicon are piled-up on the surface, exposed in the opening 20a, of the first p-type semiconductor region 18. Such a pile-up phenomenon is more noticeable particularly in the re-growth surface of a semi-polarity in the present embodiment. The semiconductor laser device 10 emitting green light includes the substrate having a semi-polar primary plane 12a of a group-III nitride semiconductor to reduce the intensity of the piezoelectric field in the active layer 16. In such a structure, the interface also exhibits semi-polarity. The semi-polar surface, which includes a large number of dangling bonds (unpaired bonds), readily incorporates donor impurities as compared with low index planes such as a c-plane, a-plane, or m-plane.

To address these issues, the semiconductor laser device 10 of the embodiment includes a highly doped p-type semiconductor layer 18c in a first p-type semiconductor region 18 constituting the region that includes an interface between the first p-type semiconductor region 18 and the second p-type semiconductor region 22. In the present example, the highly doped p-type semiconductor layer 18c of the first p-type semiconductor region 18 is in contact with the second p-type semiconductor region 22. The highly doped p-type semiconductor layer 18c has an extremely high concentration of the p-type impurity (dopant) of 1×10²⁰ cm⁻³ or greater. The (dopant) concentration of the highly doped p-type semiconductor layer 18c may be 4×10²¹ cm⁻³ or less.

As described above, in the re-growth of the second p-type semiconductor region 22 onto the first p-type semiconductor region 18, donor impurities, such as oxygen and silicon, are piled-up on the surface of the first p-type semiconductor region 18. In the semiconductor laser device 10, the diffusion of p-type impurity (dopant) of the highly doped p-type semiconductor layer 18c, however, compensates for the donor impurity to reduce phenomena (for example, an increase in a threshold current density and drive voltage) that the donor impurity causes. Accordingly, the semiconductor laser device 10 can reduce the effects caused by the n-type impurity present in the re-growth surface of semi-polarity.

The highly doped p-type semiconductor layer 18c preferably has a thickness of 10 nm or less as described in an example. The findings by the inventors indicate that the half width of the n-type impurity concentration profile in a thickness direction in the re-growth surface is approximately 10 nm and that the highly doped p-type semiconductor layer 18c having a thickness less than 10 nm allows the region having an extremely high concentration of a p-type impurity not to broaden significantly larger than the region containing donor impurities thereon, and can hold excellent device performances of the semiconductor laser device 10.

The highly doped p-type semiconductor layer 18c may be provided only in the first p-type semiconductor region 18 as described in the embodiment. The semiconductor laser device 10 having such a structure can appropriately provide the advantages described above. The highly doped p-type semiconductor layer may be grown during the growth of the second p-type semiconductor region 22 in the present and another embodiments. Specifically, before the growth of the p-type cladding 1 layer 22a, the highly doped p-type semiconductor layer may be re-grown on the first p-type semiconductor region 18 during the growth of the second p-type semiconductor region 22. Alternately, the highly doped p-type semiconductor layer may be provided in both of the first and second p-type semiconductor regions 18 and 22 thereacross. The semiconductor laser device 10 including the highly doped p-type semiconductors in such an arrangement can appropriately provide the technical contributions described above.

As described in the embodiment, the distance between the near-side surface, located near the first p-type semiconductor region 18, of the active layer 16 and the near-side surface, located near the active layer 16, of the highly doped p-type semiconductor layer 18c can be preferably 200 nm or greater. Such a large distance between the active layer 16 and the highly doped p-type semiconductor layer 18c can prevent the p-type (dopant) impurities in the highly doped p-type semiconductor layer 18c from absorbing light and can further prevent the reduction in lasing efficiency. The distance between the active layer 16 and the highly doped p-type semiconductor layer 18c preferably ranges from 200 nm to 500 nm. In the embodiment, the distance corresponds to the total thickness of the third upper optical guiding layer 19, the second upper optical guiding layer 18b and the first upper optical guiding layer 18a, and the total thickness can be, for example, 320 nm.

The optical absorption of p-type (dopant) impurity becomes particularly in the wavelength region of 500 nm or greater. The structure of the p-side semiconductor region according to the embodiment is preferable for a laser emission having a lasing wavelength of 500 nm or greater, because it can reduce the light absorption caused by the p-type (dopant) impurity in the highly doped p-type semiconductor layer 18c, thereby further prevent a decrease in lasing efficiency.

In the embodiment of the group-III nitride semiconductor laser device in which the p-type cladding layer is located in the opening of the current confinement layer and the p-type cladding layer forms a junction with the underlying semi-polar surface, this embodiment reduce effects caused by the donor impurity remaining in the junction interface.

The semiconductor laser device 10 includes an n-type semiconductor region, an active layer, and a group-III nitride region provided on the active layer. The active layer is provided between the n-type semiconductor region and the group-III nitride region. The group-III nitride region includes a first p-type semiconductor region, a current confinement layer, and a second p-type semiconductor region. The current confinement layer is composed of a group-III nitride. The primary surface of the first p-type semiconductor region includes semi-polarity. The first p-type semiconductor region is composed of a p-type group-III nitride semiconductor. The current confinement layer has an opening provided on the primary surface of the first p-type semiconductor region. The second p-type semiconductor region includes a p-type group-III nitride semiconductor, and is provided on the first p-type semiconductor region and on the current confinement layer. The second p-type semiconductor region is connected to the primary surface of the first p-type semiconductor region through the opening of the current confinement layer and is in contact with the primary surface of the first p-type semiconductor region. The lasing of the active layer preferably has an emission wavelength of 500 nm or greater, and the highly doped p-type semiconductor layer may be preferably separated at a distance of 200 nm or greater from the active layer.

The group-III nitride region includes a first p-type semiconductor portion, a second p-type semiconductor portion, and a third semiconductor portion. The first p-type semiconductor portion is provided in the first p-type semiconductor region. The second p-type semiconductor portion is provided in the second p-type semiconductor region. The third p-type semiconductor portion includes a contact interface of the first p-type semiconductor region with the second p-type semiconductor region. The third p-type semiconductor portion is in contact with the first p-type semiconductor portion and the second p-type semiconductor portion. The first p-type semiconductor portion contains a donor impurity. The group-III nitride region has a p-type dopant profile, which increases in the direction from the first p-type semiconductor portion toward the second p-type semiconductor portion and thereafter decreases in the direction, in the first, second, and third p-type semiconductor portions. The p-type dopant concentration of the first p-type semiconductor portion may be, for example, 1×10²⁰ cm⁻³ or greater. The p-type dopant concentration of the third p-type semiconductor portion is greater than that of the donor impurity such as silicon of the third p-type semiconductor portion. The current confinement layer may be composed of amorphous group-III nitride. The current confinement layer may be composed of polycrystalline group-III nitride. The current confinement layer comprises aluminum nitride (AlN).

An electrode is provided in contact with the second p-type semiconductor region. The second p-type semiconductor region includes a p-type cladding layer and a p-type contact layer, and the p-type cladding layer includes a region which has a p-type dopant concentration lower than that of the p-type contact layer and that of the third p-type semiconductor portion.

The primary surface of the first p-type semiconductor region includes first and second areas, the second area has a stripe shape and the first area is provided along the both sides of the second area. The current confinement layer is in contact with the first area, while the second p-type semiconductor region is in contact with the second area. The group-III nitride semiconductor laser device includes a pair of end faces for an optical cavity, and the second area extends from one of the pair of end faces to the other of the pair of end faces. The width of the electrode is greater than that of the opening, the width of the electrode is greater than that of the second area, and the width of the electrode is greater than that of the stripe of the second area. The width of the electrode, the width of the opening, the second area, and the width of the stripe-shaped second area are defined in the direction orthogonal to the optical cavity direction.

The n-type semiconductor region, the active layer, and the group-III nitride region are provided on the semi-polar primary surface of the substrate. The semi-polar primary surface of the substrate is composed of a group-III nitride. The substrate may be composed of a group-III nitride such as GaN. The c-axis of the group-III nitride of the substrate and the normal axis of the primary surface forms an inclination angle. The angle is in the range of 10 to 80 degrees or 100 to 170 degrees. The angle is in the range of 63 to 80 degrees or 100 to 117 degrees as in-plane angle in the plane that the c-axis and m-axis thereof define.

A group-III nitride semiconductor laser device according to the embodiment, which includes a p-type cladding layer re-grown on a current confinement layer having an opening, can moderate adverse effects caused by donor impurity in the semi-polar interface.

The scope of the present invention has been illustrated in the embodiments. However, one skilled in the art should understand that the arrangement and other details of the present invention may be changed without departing from the scope of the invention. All corrections and modifications relevant to the scope of the claims and the spirit of the invention should be included in the scope of the present invention.

What is claimed is:

1. A group-III nitride semiconductor laser device comprising:
an n-type semiconductor region comprising an n-type nitride;
an active layer comprising a group-III nitride semiconductor, the active layer being provided on the n-type semiconductor region;
a first p-type semiconductor region comprising a p-type group-III nitride semiconductor, the first p-type semiconductor region being provided on the active layer;
a current confinement layer provided on the first p-type semiconductor region, the current confinement layer including an opening, and the opening extending in a predetermined optical cavity direction; and
a second p-type semiconductor region comprising a p-type group-III nitride semiconductor and grown on the first p-type semiconductor region and the current confinement layer after the formation of the opening of the current confinement layer, an interface between the first p-type semiconductor region and the second p-type semiconductor region comprising a semi-polar surface of the group-III nitride semiconductor; and
at least one of the first or second p-type semiconductor regions including a highly doped p-type semiconductor layer so as to form the interface with the first and second p-type semiconductor regions, the highly doped p-type semiconductor layer having a p-type impurity concentration of 1×10²⁰ cm⁻³ or greater.

2. The group-III nitride semiconductor laser device according to claim 1, wherein the highly doped p-type semiconductor layer has a thickness of 10 nm or less.

3. The group-III nitride semiconductor laser device according to claim 1, wherein the highly doped p-type semiconductor layer is provided only in the first p-type semiconductor region.

4. The group-III nitride semiconductor laser device according to claim 1, wherein the active layer has one surface close to the first p-type semiconductor region and another surface away from the first p-type semiconductor region, and the highly doped p-type semiconductor layer has one surface close to the active layer and another surface away from the active layer
a distance between the one surface of the active layer and the one surface of the first p-type semiconductor region is not less than 200 nm.

5. The group-III nitride semiconductor laser device according to claim 1, wherein a lasing wavelength of the group-III nitride semiconductor laser device is 500 nm or greater.

6. The group-III nitride semiconductor laser device according to claim 1,
wherein the active layer comprise an emission wavelength of 500 nm or greater, and
the highly doped p-type semiconductor layer is separated at a distance of 200 nm or greater from the active layer.

7. A group-III nitride semiconductor laser device comprising:
an n-type semiconductor region comprising a group-III nitride semiconductor;
an active layer comprising a group-III nitride semiconductor, the active layer being provided on the n-type semiconductor region; and
a group-III nitride region provided on the active layer, the group-III nitride region comprising:
a first p-type semiconductor region comprising a p-type group-III nitride semiconductor;
a current confinement layer provided on a primary surface of the first p-type semiconductor region, the current confinement layer including an opening; and
a second p-type semiconductor region provided on the first p-type semiconductor region and the current confinement layer, the second p-type semiconductor region comprising a p-type group-III nitride semiconductor, and the second p-type semiconductor region being connected to the primary surface of the first p-type semiconductor region through the opening of the current confinement layer, and,
the current confinement layer comprising a group-III nitride;
the primary surface of the first p-type semiconductor region having semi-polarity; and
the group-III nitride region comprising a first p-type semiconductor portion in the first p-type semiconductor region, a second p-type semiconductor portion in the second p-type semiconductor region, and a third p-type semiconductor portion including an interface of the first p-type semiconductor region with the second p-type semiconductor region,
the third p-type semiconductor portion being in contact with the first p-type semiconductor portion,
the third p-type semiconductor portion being in contact with the second p-type semiconductor portion,
the third p-type semiconductor portion comprising a donor impurity,
the group-III nitride region having a p-type dopant profile defined in the first to third semiconductor portions, the p-type dopant profile increasing in a direction from the first p-type semiconductor portion to the second p-type semiconductor portion to form a peak and then decreasing in the direction.

8. The group-III nitride semiconductor laser device according to claim 7, wherein a p-type dopant concentration of the third p-type semiconductor portion is 1×10²⁰ cm⁻³ or greater.

9. The group-III nitride semiconductor laser device according to claim 7, wherein a p-type dopant concentration of the third p-type semiconductor portion is greater than a silicon concentration of the third p-type semiconductor portion.

10. The group-III nitride semiconductor laser device according to claim 7, wherein the current confinement layer comprises aluminum nitride.

11. The group-III nitride semiconductor laser device according to claim 7, wherein the current confinement layer comprises amorphous group-III nitride.

12. The group-III nitride semiconductor laser device according to claim 7, wherein the current confinement layer comprises polycrystalline group-III nitride.

13. The group-III nitride semiconductor laser device according to claim 7, wherein the second p-type semiconductor region comprise a p-type cladding layer and a p-type contact layer, and
the p-type cladding layer includes a region and the region has a p-type dopant concentration lower than a p-type dopant concentration of the p-type contact layer and a p-type dopant concentration of the third p-type semiconductor portion.

14. The group-III nitride semiconductor laser device according to claim 7,
wherein the primary surface of the first p-type semiconductor region comprises a first and a second area;
the current confinement layer is in contact with the first area of the primary surface of the first p-type semiconductor region;
the second p-type semiconductor region is in contact with the second area of the primary surface of the first p-type semiconductor region; and
the second area has a stripe shape.

15. The group-III nitride semiconductor laser device according to claim 14, comprising a pair of end faces for an optical cavity,
wherein the second area extends from one end face to the other end face.

16. The group-III nitride semiconductor laser device according to claim 15, further comprising an electrode in contact with the second p-type semiconductor region,
the electrode having a width greater than the stripe width of the second area.

17. The group-III nitride semiconductor laser device according to claim 7, further comprising a substrate having a semi-polar primary surface, the n-type semiconductor region, the active layer, and the group-III nitride region being mounted thereon,
the primary surface comprising a group-III nitride.

18. The group-III nitride semiconductor laser device according to claim 17,
wherein the substrate comprises a group-III nitride;
a c-axis of the group-III nitride of the substrate forms an angle with a normal axis of the primary surface; and
the angle is in a range of one of 10 degrees to 80 degrees or 100 degrees to 170 degrees.

19. The group-III nitride semiconductor laser device according to claim 17, wherein the angle is in a range of one of 63 degrees to 80 degrees or 100 degrees to 117 degrees.

20. The group-III nitride semiconductor laser device according to claim 7, wherein the donor impurity comprises at least any one of oxygen or silicon.
